(19) United States
(12) Patent Application Publication
(10) Pub. No.: US 2010/0147351 A1
(43) Pub. Date: Jun. 17, 2010

(54) THERMOELECTRIC CONVERSION MODULE

(75) Inventor: Koh Takahashi, Tokyo (JP)

Correspondence Address: OBLON, SPIVAK, MCCLELLAND MAIER & NEUSTADT, L.L.P., 1940 DUKE STREET, ALEXANDRIA, VA, 22314, US

(73) Assignee: Universal Entertainment Corporation, Tokyo (JP)

(21) Appl. No.: 12/669,369

(22) PCT Filed: Jun. 20, 2008
(86) PCT No.: PCT/JP08/61307

§ 371 Date: Jan. 15, 2010

(30) Foreign Application Priority Data
Jul. 20, 2007 (JP) 2007-189022

(51) Int. Cl. H01L 35/30

(52) U.S. Cl. 136/205

(57) ABSTRACT

A thermoelectric conversion module including a double angular cylinder including an inner tube and an outer tube disposed on an axis common to the inner tube and at a predetermined spacing. Electrodes are individually arranged on the opposing faces of the inner tube and the outer tube. A thermoelectric conversion element is connected with the electrodes of the faces of the thermoelectric conversion element arranged in opposing directions, one face is defined as a heating face, and the other face is defined as a cooling face. One of the inside of the inner tube and the outside of the outer tube is defined as a first fluid passage for passing a high-temperature fluid therethrough, and the other is defined as a second fluid passage for passing a low-temperature fluid therethrough.

### TECHNICAL FIELD

The present invention relates to a thermoelectric conversion module using a thermoelectric conversion element.

### BACKGROUND ART

A thermoelectric conversion element is an element for converting thermal energy to electric energy mutually. For example, if two types (a p-type and an n-type) of thermoelectric conversion elements (semi-conductor elements) are electrically connected in series and thermally in parallel and a difference in temperature is applied between each of the coupling portions, a electromotive force is generated. Then, upon connecting load to externally, electric output can be obtained. A thermoelectric conversion element for converting thermal energy to electric energy using such a thermoelectric conversion element has been known.

As an example for a thermoelectric conversion module, as shown in Japanese Unexamined Patent Application Publication No. 2004-207658, the structure (hereinafter, referred to as a flat-plate module) has been known in which a p-type thermoelectric conversion element and an n-type thermoelectric conversion element are disposed alternately at electrodes formed so as to face each other between two electrically insulating substrates of a flat plate on which insulating are treated for preventing short-circuiting between adjacent thermoelectric conversion elements to each other, and the adjacent thermoelectric conversion element to each other are connected by way of electrodes that are formed on an insulating substrate. Since the forming process of a thermoelectric conversion element is not required for this flat-plate module and manufacturing a module is easy, this flat-plate module excels in economy and versatility.

For example, such a flat-plate module forms a flat face on an outside face of a heat transfer element that surrounds a fluid passage through which a high-temperature fluid or a low-temperature fluid passes, and is attached so that this outside flat face is in close contact with one flat face of the flat-plate module. Then, since the other flat face of the flat-plate module is open to air, electric output can be obtained from the flat-plate module based on a difference in temperature in regard to the fluid.

On the other hand, one face of an insulating substrate of this flat-plate module is heated and the other face thereof is cooled, which may cause warpage (also called distortion) thereon due to thermal expansion therebetween. Such a warpage occurrence causes adhesion between the outside face of the heat transfer element enclosing the fluid passage and the flat-plate module attached so as to be in close contact with this outside face to be deteriorated, and thus heat conduction efficiency of the flat-plate module is reduced. Therefore, the warpage of the flat-plate module is prevented by using a rigid fixing member of flat-plate shape, and sandwiching and holding the flat-plate module at the outside face enclosing the fluid passage.

In this way, generating equipment using a flat-plate module has a shortcoming in that its construction becomes complex since a fixing member is required to prevent warpage.

In order to avoid such a shortcoming, a thermoelectric conversion module has been known that includes a double circular cylinder (an electric heating element) having an inner tube as a fluid passage for a high-temperature fluid, and an outer tube disposed on the same axis common to the inner tube to form a prescribed air gap so as to discharge heat in the inner tube to outside, in which the thermoelectric conversion module is configured so as to arrange electrodes on an outer circumferential face of the inner tube and an inner circumferential face of the outer face, and to sandwich a thermoelectric conversion module by the electrodes on both the one face and the other face (for example, see Japanese Unexamined Patent Application Publication No. H9-36439).

### DISCLOSURE OF THE INVENTION

### Problems to be Solved by the Invention

The thermoelectric conversion module in Japanese Unexamined Patent Application Publication No. H9-36439 is configured to arrange an electrode and a thermoelectric conversion element in a spacing of a double circular cylinder that is composed of an inner tube and an outer tube, in which the inner tube functions as a fluid passage and also functions as a substrate that transfers heat between a thermoelectric conversion element. Furthermore, it is made in configuration in which that this inner tube expands, so that compression stress is applied to the thermoelectric conversion element. Then, since the electrodes and thermoelectric conversion elements are in close contact with the outer circumferential face of the inner tube and the inner circumferential face of the outer tube, respectively, it is configured so that thermal expansion is transferred isotropically to the thermoelectric conversion element, and thus distortion and shear stress can be reduced.

However, since the thermoelectric conversion module as disclosed in Japanese Unexamined Patent Application Publication No. H9-36439, as described above, utilizes distortion caused by a difference in the thermal expansions of the inner tube and the outer tube as fluid passages for high-temperature fluid and transfers this distortion isotropically to the thermoelectric conversion element, it is necessary to configure the thermoelectric conversion module with a double circular cylinder.

Furthermore, it is not easy to incorporate the flat-plate thermoelectric conversion element or the thermoelectric conversion element that is shaped to be a circular arc into the double circular cylinder, and the constitution of the thermoelectric conversion module becomes complex. Moreover, even in the thermoelectric conversion module in Japanese Unexamined Patent Application Publication No. H9-36439, a heat-transferred face of the thermoelectric conversion element and a heat-transferring face of the heat transfer element are in close contact with each other in a circular arc shape, and each of the circular arc faces of the inner tube and the outer tube is not necessarily properly in close contact with each other due to the difference in rates of their thermal expansions. That is, the reduction of heat conduction efficiency is a concern due to a condition in which the contact of the inner tube and the outer tube of which faces are shaped to be curved and the thermoelectric conversion element of which face is shaped to be curved, which have different rates of thermal expansions, becomes a point contact due to the thermal expansion.

The present invention aims to address such a problem, and it is an object thereof to provide a thermoelectric conversion module which is simplified in constitution of the thermoelectric conversion module itself and improved in adhesion between a thermoelectric conversion element and a heat transfer element so that it has superior heat conduction efficiency as well as superior performance in assembling and maintenance.

### Means for Solving the Problems

In a first aspect, a thermoelectric conversion module includes a double angular cylinder that has an inner tube, and an outer tube disposed at a predetermined spacing on the same axis as the inner tube; electrodes that are respectively arranged on opposing faces of the inner tube and the outer tube; and a thermoelectric conversion element that is connected to the electrodes.

The thermoelectric conversion module according to the first aspect of the invention is constituted such that electrodes are respectively arranged on opposing faces of the inner tube and the outer tube of the double angular cylinder (a heat transfer element) that includes the inner tube, and the outer tube disposed at a predetermined spacing on the same axis as the inner tube while the thermoelectric conversion element is connected to the electrodes; therefore, it is possible to provide a thermoelectric conversion module which is simplified in constitution of the thermoelectric conversion module itself and improved in adhesion between a thermoelectric conversion element and a heat transfer element so that it has an excellent heat conduction efficiency as well as excellent performance in assembling and maintenance.

According to a second aspect, in the thermoelectric conversion module as described in the first aspect, the thermoelectric conversion element has one face disposed in an opposing orientation that is defined as a heating face, and the other face is defined as a cooling face, one of an inside of the inner tube and an outside of the outer tube is defined as a first fluid passage in which high-temperature fluid flows, and the other is defined as a second fluid passage in which low-temperature fluid flows, in which the thermoelectric conversion element includes: a first insulation layer that is adhered to the heating face and that is formed through the electrodes on an opposite face of the first fluid passage and second insulation layer that is fixed to the cooling face and that is formed through the electrodes on an opposite face of the second fluid passage.

Since the thermoelectric conversion module according to the second aspect of the invention is constituted such that one face of the thermoelectric conversion element is in close contact (not fixed) on a face opposite to a high-temperature side of which thermal expansion is high so as to form a first insulating layer (for example, coating an insulating material such as an insulating paste containing aluminum nitride (AIN), silica (SiO₂), and the like)) via an electrode, while the other face of the thermoelectric conversion element is fixed on a face of a low-temperature side, which has a low thermal expansion and which is disposed in a direction opposite to the face of the high-temperature side, so as to form a second insulating layer (for example, performing insulation processing such as anode oxidation processing) via an electrode, occurrence of the warpage due to the difference between thermal expansions of the sides of the heating face and the cooling face can be suppressed.

Here, since the thermoelectric conversion module in Japanese Unexamined Patent Application Publication No. H9-36439, as described above, is constituted to use the distortion due to the thermal expansions of the inner tube and the outer tube so as to transfer this distortion to the thermoelectric conversion element isotropically, the problem of warpage occurred at the thermoelectric conversion module is not solved. Therefore, it is impossible to be applied to a flat-plate module. However, in a case of constituting a power generating apparatus to use the thermoelectric conversion module according to the invention described in the second aspect as a flat-plate module, the distortion of the flat-plate module due to the difference of thermal expansions between the heating face side and the cooling face side and the occurrence of shear stress applied to the thermoelectric conversion element can be suppressed and it is no longer necessary to use a fixing member for preventing warpage of the flat-plate module, and therefore it is possible to provide a thermoelectric conversion module that can simplify the constitution of the thermoelectric conversion module as well as excel in economy and versatility.

According to a third aspect, in the thermoelectric conversion module as described in the second aspect, a radiating member is disposed on a face defined as the second fluid passage.

In the thermoelectric conversion module according to the invention as described in the third aspect, since the radiating member (for example, a radiating fin) is disposed on a face defined as the second fluid passage of the double angular cylinder, it is possible to suppress warpage occurred due to the thermal expansions between the inner tube or the outer tube of the double angular cylinder and the thermoelectric conversion element, and since the warpage from the inner face of the inner tube or the outer face of the outer tube of the double angular cylinder can be suppressed by the radiating member thus disposed, it is, therefore, possible to improve adhesion between the thermoelectric conversion module and the heat transfer element. Furthermore, the radiating member can also function as a reinforcing material for reinforcing the double angular cylinder.

According to a fourth aspect, in the thermoelectric conversion module as described in any one of the first to third aspects, the thermoelectric conversion element is formed in a flat-plate shape, and an outer face of the inner tube is formed in an flat-plate shape and extends in an axial direction.

In the thermoelectric conversion module according to the invention as described in the fourth aspect, the thermoelectric conversion element is formed in a flat-plate shape, and an outer face of the inner tube is formed in a flat-plate shape and extends in an axial direction. In this way, in the thermoelectric conversion module according to the invention as described in the fourth aspect, a heat-transferred face of the thermoelectric conversion element, which is formed in flat-plate shape, and a heat-transferring face of the heat transfer element that extends in an axial direction, which is formed in flat-plate shape, are fixed or in close contact with each other on a flat face, and thus a heat conduction area can be made larger and electric output can be improved. Moreover, it is possible to increase the size of the thermoelectric conversion module of the present invention.

According to a fifth aspect, in the thermoelectric conversion module as described in any one of the first to fourth aspects, the thermoelectric conversion element is a sintered cell containing a composite metal oxide.

In the thermoelectric conversion module according to the invention as described in the fifth aspect, since the thermoelectric conversion element is a sintered cell containing a composite metal oxide, it is possible to overcome the reduction of the thermal conversion efficiency due to irregularity of semiconducting properties occurring when using p-type and n-type thermoelectric conversion elements in the thermoelectric conversion module.

According to a sixth aspect, in the thermoelectric conversion module as described in the fifth aspect, the electrodes are obtained by applying a conductive paste to the sintered cell, and sintering.

Since the thermoelectric conversion module according to the invention as described in the sixth aspect is constituted to obtain an electrode by applying a conductive paste to the sintered cell and sintering (integrating the thermoelectric conversion element with the electrode), it is no longer necessary to perform an operation to arrange an electrode to the thermoelectric conversion element separately, which can facilitate assembly of the thermoelectric conversion module and simplify the thermoelectric conversion module.

According to a seventh aspect, in the thermoelectric conversion module as described in any one of the first to sixth aspects, each of the thermoelectric conversion elements is molded from an identical material.

Since the thermoelectric conversion module according to the invention as described in the seventh aspect is constituted such that each of the thermoelectric conversion elements is molded from the same material and with the identical size, it is possible to unify the electrical characteristics of each of the thermoelectric conversion element. Therefore, it is possible to improve the thermoelectric conversion efficiency, compared to conventional thermoelectric conversion modules in which p-type and n-type thermoelectric conversion elements are disposed alternately.

According to an eighth aspect, the thermoelectric conversion module as described in any one of the first to seventh aspects further includes a conductive member of a predetermined shape electrically connecting with a second electrode that is different from the electrode, in which the conductive member has first fitting portion that fits together with and is secured to one of the electrodes, and a lead portion that is electrically connected to the second electrode, which is different from the electrode with the first fitting portion.

In the thermoelectric conversion module according to the invention as described in the eighth aspect, since the first fitting portion and the lead portion are integrated with each other in the conductive member of a predetermined shape electrically connecting the electrode to a second electrode that is different from the electrode that is disposed at the thermoelectric conversion element, secure conduction can be obtained, which improves electrical reliability.

According to a ninth aspect, in the thermoelectric conversion module as described in the eighth aspect, the second electrode is an external electrode to which the thermoelectric conversion module connects electrically.

Since the thermoelectric conversion module according to the invention as described in the ninth aspect can perform a connection with an external electrode easily and securely by way of the conductive member, it excels in incorporation to another apparatus, which can improve electrical reliability.

According to a tenth aspect, in the thermoelectric conversion module as described in the eighth aspect, the second electrode is the electrode of a second thermoelectric conversion element, and the lead portion includes a second fitting portion that fits together with and is secured to another of the electrodes of the second thermoelectric conversion element.

In the thermoelectric conversion module according to the invention as described in the tenth aspect, since the lead portion includes the second fitting portion that fits together with and is secured to another of the electrodes of the second thermoelectric conversion element, the electrodes that are formed at the thermoelectric conversion element can easily and securely be electrically connected by way of the first and second fitting portions, which can prevent the occurrence of conduction failure.

According to an eleventh aspect, in the thermoelectric conversion module as described in any one of the eighth to tenth aspects, the conductive member includes: a first connector that forms a thermoelectric conversion element array by way of connecting in a predetermined direction a plurality of the thermoelectric conversion elements, which are arranged in parallel, to each other; and a second connector that electrically connects the second electrode and one of the electrodes of any one of a first or last thermoelectric conversion element of the thermoelectric conversion element array connected to the first connector.

In the thermoelectric conversion module according to the invention as described in the eleventh aspect, since the conductive member includes a first connector that forms a thermoelectric conversion element array by way of connecting in a predetermined direction a plurality of the thermoelectric conversion elements, which are arranged in parallel, to each other, and a second connector that electrically connects the second electrode and one of the electrodes of any one of a first or last thermoelectric conversion element of the thermoelectric conversion element array connected to the first connector, it is possible to use connectors according to connection types of the thermoelectric conversion element and to perform a connection with various types of thermoelectric conversion element arrays easily and securely, depending on the application.

According to a twelfth aspect, in the thermoelectric conversion module as described in the eleventh aspect, the second electrode connected by the second connector is another one of the electrodes of any one of a first or last thermoelectric conversion element of another of the thermoelectric conversion element arrays.

In the thermoelectric conversion module according to the invention as described in the twelfth aspect, since a plurality of the thermoelectric conversion element arrays can be connected electrically with each other by way of the second connector, it is possible to perform a connection with various types of thermoelectric conversion element arrays easily and securely, depending on the application.

### EFFECTS OF THE INVENTION

Since the thermoelectric conversion module according to the present invention is constituted such that electrodes are respectively arranged on opposing faces of the inner tube and the outer tube of the double angular cylinder (a heat transfer element) that includes the inner tube, and the outer tube disposed at a predetermined spacing on the same axis as the inner tube and the thermoelectric conversion element that is connected to the electrodes, it is possible to provide a thermoelectric conversion module which is simplified in constitution of the thermoelectric conversion module itself and improved in adhesion between a thermoelectric conversion element and a heat transfer element so that it has superior heat conduction efficiency as well as superior performance in assembling and maintenance.

### BRIEF DESCRIPTION OF THE DRAWINGS

FIG. 1 is a perspective exploded view of a thermoelectric conversion module according to one embodiment of the present invention, and illustrates a portion of a sectioned outer tube;

FIG. 2 is a perspective outline view of the thermoelectric conversion module according to the embodiment in which a radiating member is arranged around the outer tube;

FIG. 3 is a view of a right side face of the thermoelectric conversion module according to the embodiment;

FIG. 4 is a perspective outline view of a thermoelectric conversion element used for the thermoelectric conversion module according to the embodiment;

FIG. 5 is a vertical cross-sectional view of a thermoelectric conversion element array used for the thermoelectric conversion module according to the embodiment;

FIG. 6 is a view illustrating a first connector used for the thermoelectric conversion module according to the embodiment, with FIG. 6(A) being an expanded view of the first connector, FIG. 6(B) being a right side face view of the first connector, FIG. 6(C) being a perspective outline view illustrating a condition in which a pair of thermal conversion elements is connected by the first connector, and FIG. 6(D) being a front view of the first connector;

FIG. 7 is a view illustrating a relationship between a thermoelectric conversion element and the first connector, with FIG. 7(A) being a perspective outline view illustrating a condition in which the first connector is connected to the thermoelectric conversion element, which are arranged to be aligned, and FIG. 7(B) being a view illustrating a condition in which the thermoelectric conversion element and the first connector according to a modified example are arranged so as to face each other;

FIG. 8 is a view illustrating a second connector used for the thermoelectric conversion module according to the embodiment, with FIG. 8(A) being a development view of the second connector, FIG. 8(B) being a right side face view of the second connector, and FIG. 8(C) being a perspective outline view illustrating a condition in which a pair of adjacent thermoelectric conversion elements is connected by the second connector;

FIG. 9 is an expanded view of a third connector used for the thermoelectric conversion module according to the embodiment;

FIG. 10 is a view illustrating a third connector used for the thermoelectric conversion module according to the embodiment, with FIG. 10(A) being a right side face view of the third connector, FIG. 10(B) being a perspective outline view illustrating a condition in which the third connector is connected to the thermoelectric conversion element, and FIG. 10 (C) being a front view illustrating the third connector;

FIG. 11 is a view illustrating the other third connector used for the thermoelectric conversion module according to the embodiment, with FIG. 11(A) being a right side face view of the other third connector, FIG. 11(B) being a perspective outline view illustrating a condition in which the other third connector is connected to the thermoelectric conversion element, and FIG. 11 (C) being a front view illustrating the other third connector;

FIG. 12 is a layout view of a test instrument upon measuring characteristics of the thermoelectric conversion module shown in FIG. 1; and

FIG. 13 is a view illustrating a usage example of the thermoelectric conversion module shown in FIG. 1.

### EXPLANATION OF REFERENCE NUMERALS

10 thermoelectric conversion module
11 thermoelectric conversion array
12 thermoelectric conversion element (single element)
12c, 12d first and second electrodes (first and second electrode faces)
13 outer tube
14 inner tube
15 double angular cylinder

### PREFERRED MODE FOR CARRYING OUT THE INVENTION

In the following, an embodiment of the present invention is described with reference to the drawings.

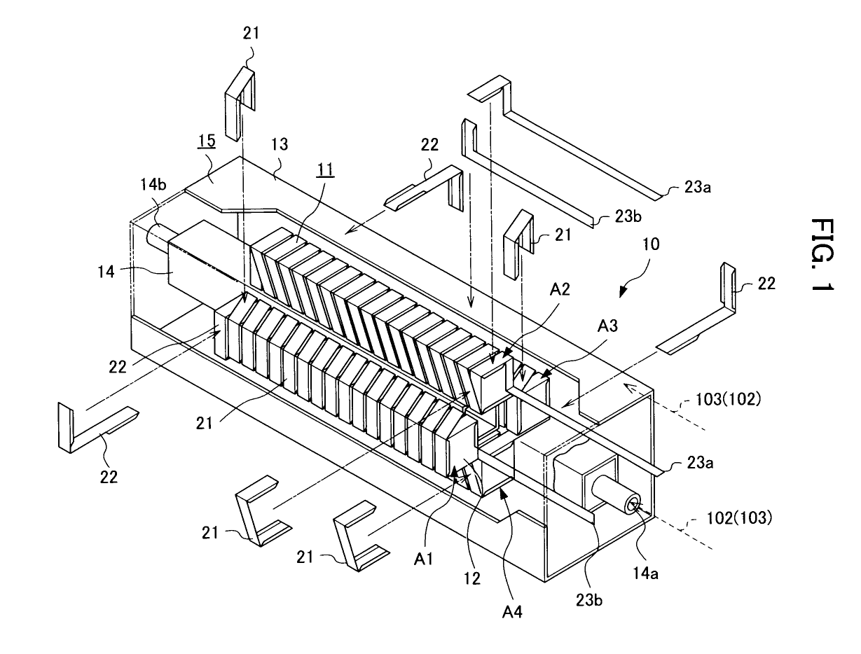

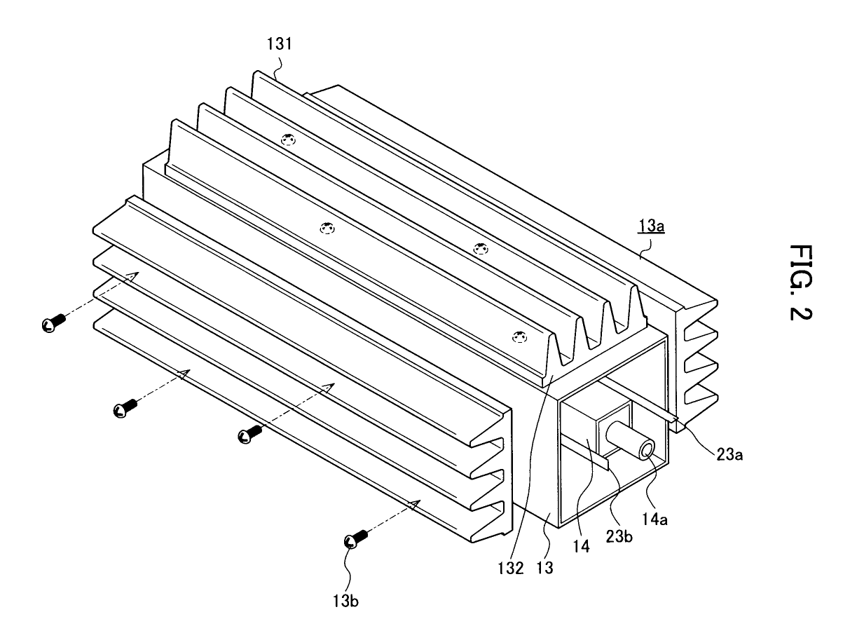

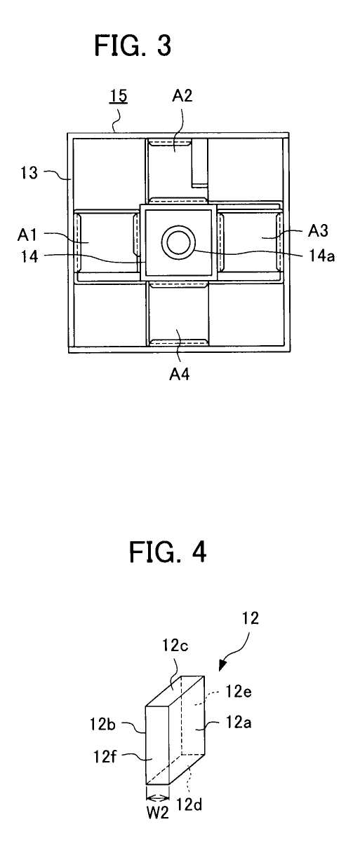

FIG. 1 is a perspective exploded view of a thermoelectric conversion module according to one embodiment of the present invention, and illustrates a portion of a sectioned outer tube. FIG. 2 is a perspective outline view of the thermoelectric conversion module according to the embodiment in which a radiating member is arranged around the outer tube. FIG. 3 is a view of a right side face of the thermoelectric conversion module according to the embodiment. FIG. 4 is a perspective outline view of a thermoelectric conversion element used for the thermoelectric conversion module according to the embodiment.

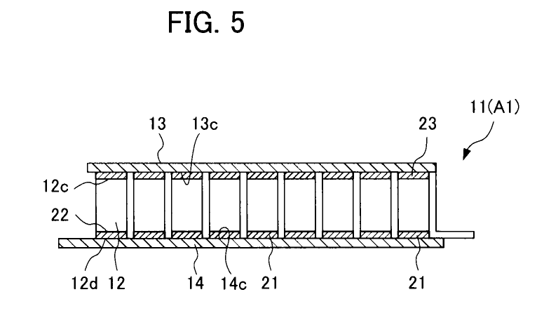

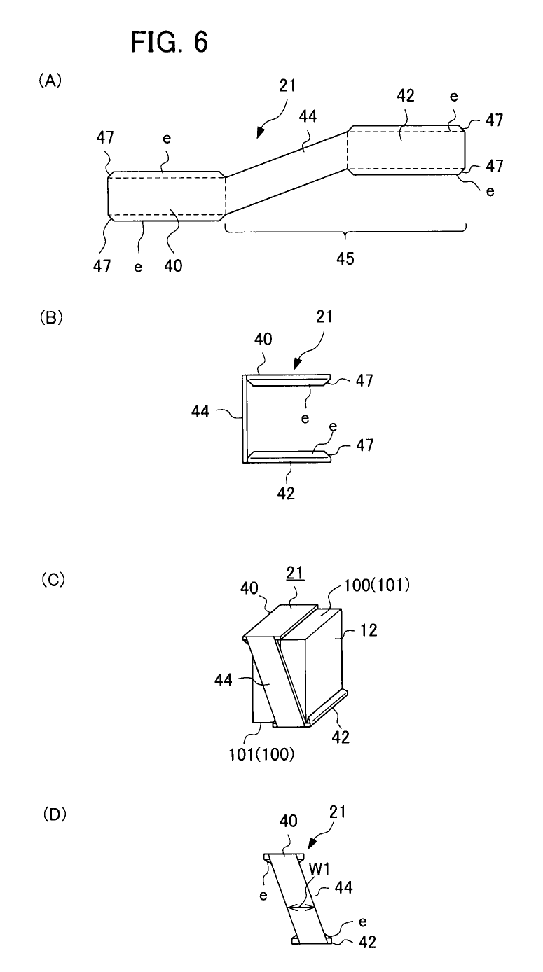

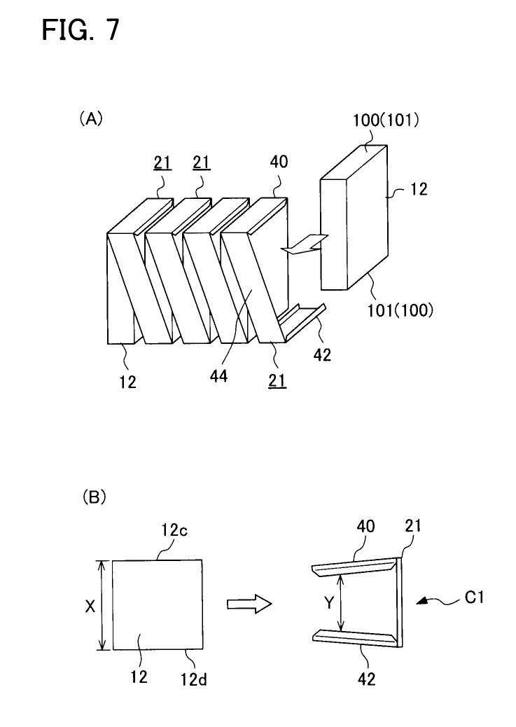

FIG. 5 is a vertical cross-sectional view of a thermoelectric conversion element array used for the thermoelectric conversion module according to the embodiment. FIG. 6 is a view illustrating a first connector used for the thermoelectric conversion module according to the embodiment, which FIG. 6(A) being an expanded view of the first connector, FIG. 6(B) being a right side face view of the first connector, FIG. 6(C) being a perspective outline view illustrating a condition in which a pair of thermal conversion elements is connected by the first connector, and FIG. 6(D) being a front view of the first connector. FIG. 7 is a view illustrating a relationship between a thermoelectric conversion element and the first connector, with FIG. 7(A) being a perspective outline view illustrating a condition in which the first connector is connected to the thermoelectric conversion element that are arranged adjacent to each other, and FIG. 7(B) being a view illustrating a condition in which the thermoelectric conversion element and the first connector according to a modified example are arranged so as to face each other.

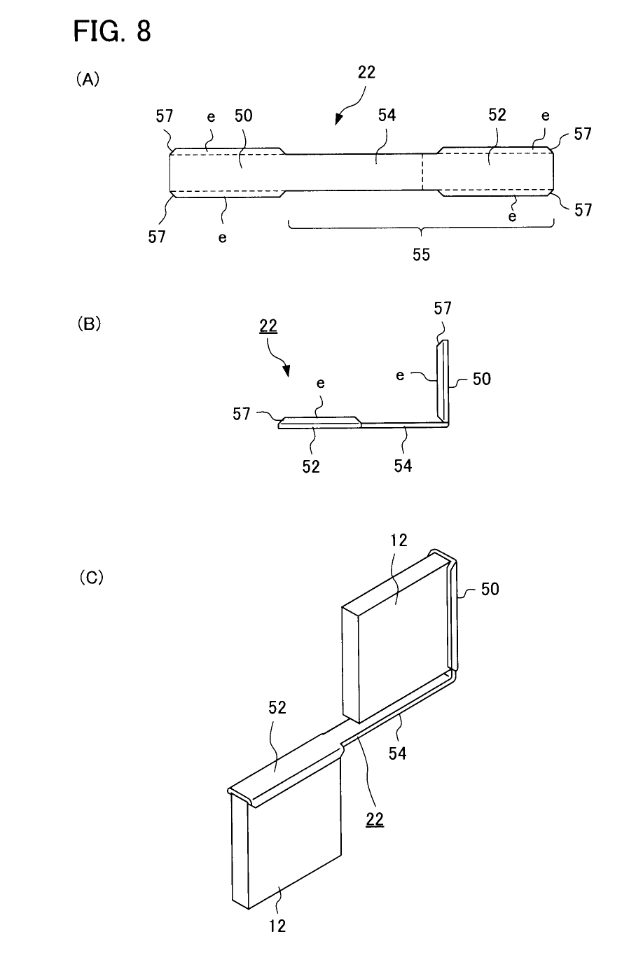

FIG. 8 is a view illustrating a second connector used for the thermoelectric conversion module according to the embodiment, with FIG. 8(A) being a development view of the second connector, FIG. 8(B) being a right side face view of the second connector, and FIG. 8(C) being a perspective outline view illustrating in a condition in which a pair of adjacent thermoelectric conversion elements is connected by the second connector.

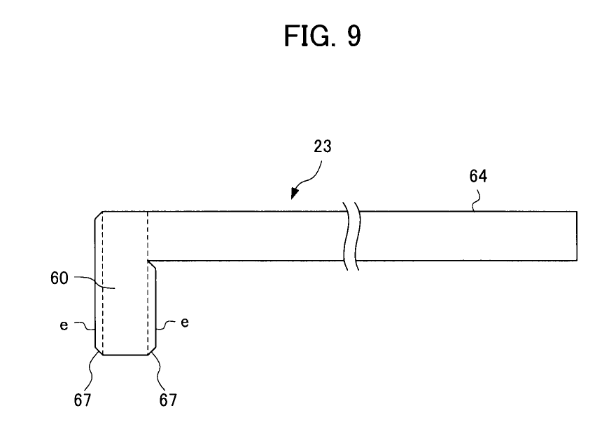

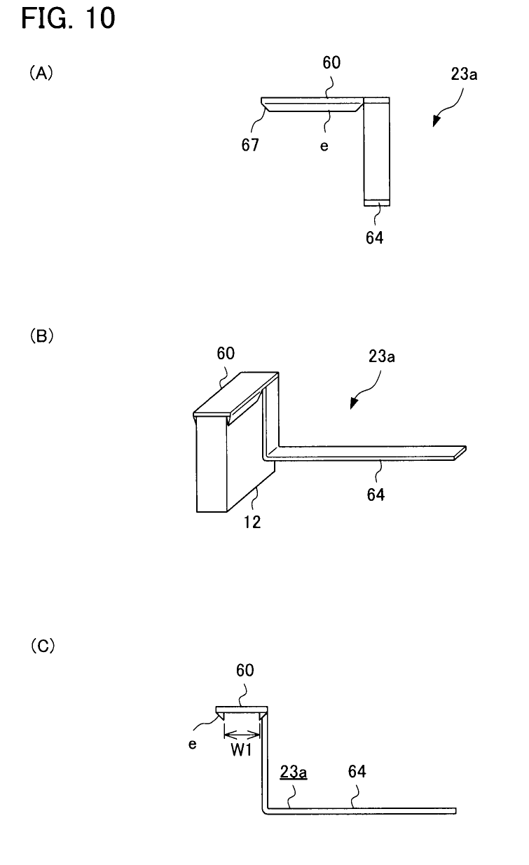

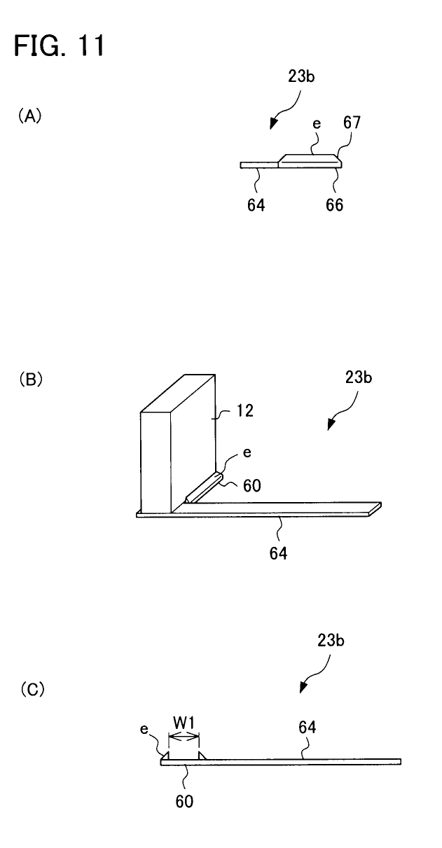

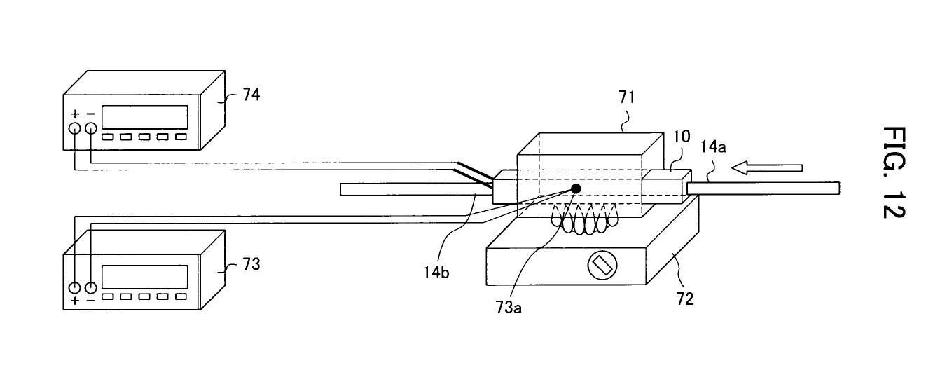

FIG. 9 is an expanded view of a third connector used for the thermoelectric conversion module according to the embodiment. FIG. 10 is a view illustrating a third connector used for the thermoelectric conversion module according to the embodiment, with FIG. 10(A) being a right side face view of the third connector, FIG. 10(B) being a perspective outline view illustrating a condition in which the third connector is connected to the thermoelectric conversion element, and FIG. 10 (C) being a front view illustrating the third connector. FIG. 11 is a view illustrating the other third connector used for the thermoelectric conversion module according to the embodiment, with FIG. 11(A) being a right side face view of the other third connector, FIG. 11(B) being a perspective outline view illustrating a condition in which the other third connector is connected to the thermoelectric conversion element, and FIG. 11 (C) being a front view illustrating the other third connector.

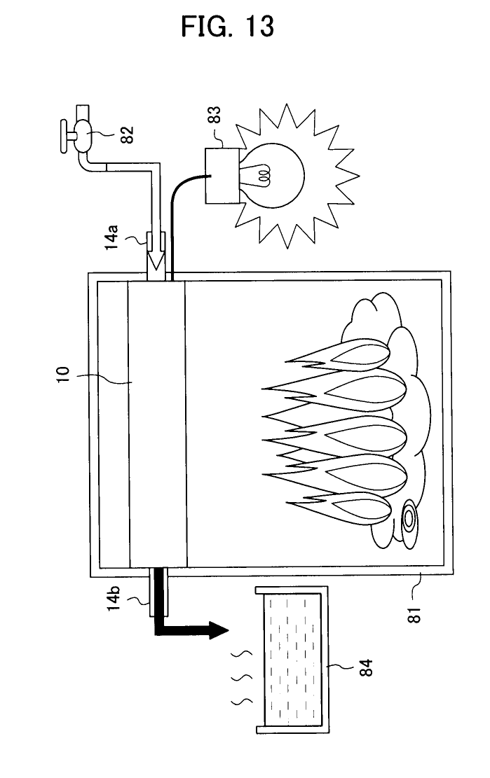

FIG. 12 is a layout view of a test instrument upon measuring characteristics of the thermoelectric conversion module shown in FIG. 1. FIG. 13 is a view illustrating a usage example of the thermoelectric conversion module shown in FIG. 1.

Firstly, a constitution of a thermoelectric conversion module according to the present invention is described. In FIGS. 1 and 3, a thermoelectric conversion module 10 includes a plurality of thermoelectric conversion element arrays 11, and each of the thermoelectric conversion element arrays 11 includes a plurality of thermoelectric conversion elements (hereinafter, referred to as a single element). Then, electrodes are formed on principal surfaces of these single elements 12 facing each other as described later, the single elements 12 are connected by way of a conductive member (hereinafter, referred to as a connector) to form the thermoelectric conversion element array 11.

In FIG. 1, the thermoelectric conversion module 10 includes a metallic outer tube 13 of a angular cylindrical shape and a metallic inner tube 14 of a angular cylinder. The outer tube 13 and the inner tube 14 are disposed with a spacing portion on the same axis. In the embodiments in FIGS. 1 and 3, the outer tube 13 and the inner tube 14 are formed to be rectangular shapes and have four flat faces that extend in a predetermined direction. Then, the outer tube 13 and the inner tube 14 are arranged in a condition in which an inner face of the outer tube 13 and an outer face of the inner tube 14 face each other. A double angular cylinder 15 is composed of the outer tube 13 and the inner tube 14.

In FIGS. 1 and 3, a plurality of the thermoelectric conversion element arrays 11 is arranged between the inner face of the outer tube 13 and the outer face of the inner tube 14 (the spacing portion as previously described). In other words, each of the thermoelectric conversion element arrays 11 is disposed on the four outer faces (flat faces) of the inner tube 14, and the thermoelectric conversion element arrays 11 abut the inner faces of the outer tube 13. In the embodiments in FIGS. 1 and 3, four thermoelectric conversion element arrays 11 are arranged, which are respectively represented as first to fourth alignments A1 to A4.

In FIGS. 1 and 3, each alignment A1 to A4 of the thermoelectric conversion element arrays 11 is electrically connected using first to third connectors 21 to 23. It should be noted that the third connector 23 indicates third connectors 23a and 23b as described later (see FIGS. 10 and 11). With regard to each thermoelectric conversion element array 11, for example, fifty single elements 12 may be connected in series, and each alignment A1 to A4 of the thermoelectric conversion element arrays 11 are connected with each other in series.

Next, the thermoelectric conversion element (the single element) is described. Each single element 12 as shown is an element that alternately converts thermal energy to electric energy with use of the Peltier effect or the Seebeck effect, and is made from an identical material. Here, each single element 12 is set to have the same size (for example, a square of 8.3 mm×8.3 mm and thickness of 2.45 mm), shape, and material (such as an identical conductive-type semiconductor). More specifically, each single element 12 is a sintered cell that is made from a composite metal oxide and, for example, a perovskite-type composite oxide-based element (as an example, a CaMnO₃-based single element) is used therefor. As the perovskite-type composite oxide used for this single element, it is preferable that Ca₍₁₋ₓ₎YₓMnO₃ (where Y is at least one type of element selected from yttrium and lanthanoid, and 0.01≦x≦0.05) is used. Generally, like a semiconductor such as Bi—Te used for a sintered cell, the perovskite-type composite oxide-based element has superior characteristics without including rare elements and environmentally unfriendly materials, having high heat resistance, low deterioration of electric heating characteristics over long time use at high temperature, and the like. In addition, it is not preferable to include a cobalt containing oxide, which is expensive, as a main component of a sintered cell in view of general usage and increase in size of the thermoelectric conversion module. On the other hand, by using Ca₍₁₋ₓ₎YₓMnO₃ (where Y is at least one type of element selected from yttrium and lanthanoid and 0.01≦x≦0.05) as this perovskite-type composite oxide, it is possible to further increase heat resistance of a sintered cell at high temperature and achieve high-volume production and increase size at an accordable price. It should be noted that a semiconductor such as Bi—Te has low heat resistance (high-temperature stability) in a high temperature region and difficulty in usage in a high temperature region, and includes expensive and toxic rare elements (such as Te and Ge), which raise manufacturing costs and increase the environmental burden. In addition, as a material used for a sintered cell, although a cobalt containing oxide, which does not include the abovementioned rare elements and environmentally unfriendly materials, excels in high-temperature stability, and has reduced environmental burden, has gained attention, cobalt is expensive as described above, an is not preferable in view of high-volume production and an increase in size of the thermoelectric conversion module.

As shown in FIG. 4, the single element 12 is formed in a cubic shape (a flat-plate shape). The single element 12 includes a pair of principal faces 12a and 12b, which face each other and has the largest surface area. Then, the single element 12 includes first and second electrodes (also referred to as electrode faces) 12c and 12d that are arranged at both sides of the pair of the principal faces 12a and 12b, and a pair of the remaining lateral faces 12e and 12f. In FIG. 4, in the single element 12, one of the first and second electrode faces 12c and 12d may be defined as a heating face and the other thereof may be defined as a cooling face, and a difference in temperature between the heating face and the cooling face generates electricity. It should be noted that the pair of the remaining lateral faces 12e and 12f may be electrode faces, respectively. Furthermore, as described later, a first insulating layer is formed at one of the first and second electrode faces 12c and 12d, and a second insulating layer is formed at the other of the first and second electrode faces 12c and 12d.

A constitution of the thermoelectric conversion module according to the present invention is described again. As shown in FIG. 2, it is preferable to arrange a radiating member on an outer surface of the outer tube 13. In the embodiment in FIG. 2, a radiating fin 13a that is integrally formed by a plurality of fins 131 and radiating plates 132 is used as the radiating member as previously described. Then, a plurality of the fins 131 is formed in a ridged shape substantially in parallel so as to rise from the radiating plate 132. The radiating plate 132 includes a flat mounting surface. It is preferable that the radiating fin 13a is made of a metallic body that excels in a radiating characteristic such as aluminum, and a plurality of the fins 131 and the radiating plates 132 extend in an axial direction of the outer tube 13.

In FIG. 2, the radiating fin 13a is fixed on an outer surface of the outer tube 13 using fastener such as a screw 13b. In the embodiment in FIG. 2, although the radiating fins 13a are fixed at three outer faces of the outer tube 13, the radiating fin 13a may be fixed at one outer face of the outer tube 13, the radiating fin 13a may be fixed at a pair of outer faces of the outer tube 13 that are oriented oppositely, and the radiating fin 13a may be fixed at four outer faces of the outer tube 13. One or more of the radiating fin 13a is arranged appropriately, depending on a radiating characteristic to be expected.

When the radiating fin 13a is fixed to the outer surface of the outer tube 13 in this way, heat radiation of the thermoelectric conversion module 10 is promoted by the radiating fin 13a. Furthermore, since the radiating fin 13a forms a plurality of fins of ridged shape substantially in parallel, rigidity with respect to bending moment is high. By fixing the radiating fin 13a with such high rigidity at the outer surface of the outer tube 13, it is possible to efficiently suppress warpage (distortion) of the outer tube 13 due to thermal expansion. That is, adhesion between the single element 12 and the outer tube 13 becomes favorable. As a result of this, it is possible to improve thermal efficiency of the thermoelectric conversion module. It should be noted that the radiating fin 13a can also function as a reinforcing material for reinforcing the thermoelectric conversion module 10 that is composed of a double angular cylinder.

In FIG. 5, if focusing on one thermoelectric conversion element array 11 (for example, alignment A1), a first electrode face 12c at the single element 12 faces an inner face 13c of the outer tube 13. On the other hand, a second electrode face 12d of the single element 12 faces an outer face 14c of the inner tube 14. Then, the thermoelectric conversion element array 11 is arranged at a spacing portion that is defined by the outer tube 13 and the inner tube 14. As shown in FIG. 5, each single element 12 is aligned so as to be substantially vertical with respect to the outer tube 13 and the inner tube 14. In each single element 12, the first and second electrode faces 12c and 12d are in contact with the inner face 13c of the outer tube 13 and the outer face 14c of the inner tube 14, respectively, via the first to third connectors 21 to 23 (see FIG. 5).

In FIGS. 1 and 3, for single elements 12 that are adjacent in the thermoelectric conversion element array 11, a first electrode face 12c of one single element 12 and a second electrode face 12d of the other single element 12 are electrically connected via connectors having a predetermined shape (the first to third connectors 21 to 23).

In FIGS. 1 and 3, the first connector 21 is formed in a U-shape and electrically connects the single elements 12 and 12 at each of the thermoelectric conversion element arrays 11 (see FIGS. 6 and 7). The second connector 22 is formed in an L-shape and electrically connects a last single element 12 of the one thermoelectric conversion element array 11 and a first single element 12 of the other thermoelectric conversion element array 11 at a pair of the adjacent thermoelectric conversion element arrays 11 and 11 (see FIG. 8).

Furthermore, in FIGS. 1 and 3, the third connector 23 electrically connects a first single element 12 and a last single element 12 of the thermoelectric conversion element arrays 11 that are connected in series and an external electrode as another electrode (not shown). It is preferable for these first to third connectors 21 to 23 to use silver, copper alloy (for example, brass), stainless steel (SUS), and the like, which are not likely to rust in a high-temperature oxidizing atmosphere.

Next, a constitution of the first connector is described. In FIG. 6, the first connector 21 includes a first fitting portion 40 and a lead portion 45 (see FIG. 6(A)). The first fitting portion 40 is attached by fitting into the first or second electrode faces 12c and 12d at the single element 12 (see FIG. 4). The lead portion 45 connects the first fitting portion 40 to another electrode. Furthermore, the lead portion 45 includes a second fitting portion 42 and a connecting portion 44. The second fitting portion 42 is fitted into the first or second electrode faces 12c and 12d (another electrode) at another single element 12 and attached thereto. The connecting portion 44 connects the first fitting portion 40 and the second fitting portion 42.

In FIG. 6, the first fitting portion 40 forms at both ends thereof a pair of fold strips e and e that holds end portions of a pair of principal faces 12a and 12b from both sides (see FIG. 4). Similarly, the second fitting portion 42 forms at both ends thereof a pair of fold strips e and e that sandwiches and holds end portions of a pair of principal faces 12a and 12b from both sides (see FIG. 4). A chamfered portion 47 that is cut out at an angle is provided at both end portions of each fold strip.

In FIG. 6, regarding the first connector 21, an unfolded plate shown in FIG. 6(A) is folded to form the U-shape first connector 21 shown in FIG. 6(B). The first connector 21 may be formed so that, first, the pair of the fold strips e and e is folded at an angle not less than a right angle, and then folded substantially at a right angle at the boundary between the first and second fitting portions 40 and 42 and the connecting portion 44. The first connector 21 may be folded to be formed into a bundle without undergoing two folding steps. Then, the first connector 21 fits the first fitting portion 40 into the one first electrode face 12c among the adjacent single elements 12 at the identical thermoelectric conversion element array 11, and fits the second fitting portion 42 into the other second electrode face 12d (see FIGS. 4 and 6(C)). By being assembled in this way, the connecting portion 44 is oriented in an inclined orientation from above to below, and thus the adjacent single elements 12 and 12 are connected electrically.

As shown in FIG. 1, at the thermoelectric conversion element array 11, the first connectors 21 are secured so that the connecting portions 44 are arranged at an angle in an identical direction to each other (see FIG. 6(C)). Furthermore, at the adjacent thermoelectric conversion element arrays 11 and 11, the first connector 21 is secured so that the inclined directions thereof are in opposite directions (see FIG. 6(C)). Moreover, sides on which the connecting portions 44 are disposed with respect to the pair of the principal surfaces 12a and 12b are in an identical direction in the identical thermoelectric conversion element array 11, whereas the sides thereof are in opposite directions to each other between the adjacent thermoelectric conversion element arrays 11. That is, the connecting portions 44 are disposed at a side of the lateral face 12e in the one thermoelectric conversion element array 11, whereas the connecting portions 44 are disposed at a side of the lateral side 12f in the other thermoelectric conversion element array 11 (see FIGS. 4 and 6(C)).

In FIG. 6, the fold strip e is folded at an angle not less than a right angle, and an installation width W1 (see FIG. 6(D)) of the first and second fitting portions 40 and 42 of the first connector 21 is set so as to be smaller than the width W2 (see FIG. 4) of the first and second electrode faces 12c and 12d of the single element 12.

With this constitution, when the single element 12 is pushed into the first and second fitting portions 40 and 42 to attach, the pair of the fold strips e and e is pushed to be elastically widened so that the first and second electrode faces 12c and 12d of the single element 12 can be secured to the first and second fitting portions 40 and 42, respectively, in a so-called one-touch style. Furthermore, the single element 12 and the first connector 21 can be joined without space. As a result of this, conduction failure or contact failure between the single element 12 and the first connector 21 can be prevented (see FIGS. 4 and 6(C)).

More specifically, as shown in FIG. 6(A), since the chamfered portions 47 are formed at both ends of the pair of the folded strips e and e, as shown in FIG. 7(A), the second electrode faces 12c and 12d of the single element 12 are allowed to be slid and pushed into the insides of the first and second fitting portions 40 and 42. As a result of this, the pair of the folded strips e and e can be pushed to be elastically and smoothly widened, so that mounting the single element 12 to the first connector 21 can be facilitated.

Next, the constitution of the second connector is described. In FIG. 8, a second connector 22 includes a first fitting portion 50 and a lead portion 55. The first fitting portion 50 is fitted into the first and second electrode faces 12c and 12d of the single element 12 and secured (see FIG. 4). The lead portion 55 electrically connects the first fitting portion 50 to another electrode. Furthermore, the lead portion 55 includes the second fitting portion 52 and a connecting portion 54. The second fitting portion 52 is fitted into the first or second electrode faces 12c and 12d (another electrode) of a separate single element 12 and secured. The connecting portion 54 connects the first fitting portion 50 with the second fitting portion 52.

In FIG. 8, the first fitting portion 50 forms at both ends thereof a pair of fold strips e and e that holds end portions of a pair of principal faces 12a and 12b from both sides (see FIG. 4). Similarly, the second fitting portion 52 forms at both ends thereof a pair of fold strips e and e that sandwiches and holds end portions of a pair of principal faces 12a and 12b from both sides (see FIG. 4). A chamfered portion 57 that is cut out at an angle is provided at both end portions of each fold strip.

In FIG. 8, regarding the second connector 22, an unfolded plate shown in FIG. 8(A) is folded to form the U-shape second connector 22 shown in FIG. 8(B). The second connector 22 may be formed so that, first, the pair of the fold strips e and e is folded at an angle not less than a right angle, and then folded substantially at a right angle at the boundary between the second fitting portions 52 and the connecting portion 44. The second connector 22 may be folded to be formed in a lump without undergoing two folding steps. In FIG. 8(C), the first fitting portion 50 may be fitted into the first electrode face 12c (or the second electrode face 12d) of the single element 12 that is disposed to be last of the one thermoelectric conversion element array 11, and the second fitting portion 52 is fitted into the second electrode face 12d (or the first electrode face 12c) of the single element 12 that is disposed to be first of the other thermoelectric conversion element array 11. With such assembling, the second connector 22 electrically connects the adjacent thermoelectric conversion element arrays 11 and 11 (see FIG. 1).

In FIG. 8, the fold strip e is folded at an angle not less than a right angle, and an installation width of the first and second fitting portions 50 and 52 of the second connector 22 is set so as to be smaller than the width W2 (see FIG. 4) of the first and second electrode faces 12c and 12d of the single element 12.

With this constitution, when the single element 12 is pushed into the first and second fitting portions 50 and 52 to attach, the pair of the fold strips e and e is pushed to be elastically widened so that the first and second electrode faces 12c and 12d can be secured to the first and second fitting portions 50 and 52, respectively, in a so-called one-touch style. Furthermore, the single element 12 and the second connector 22 can be joined without space. As a result of this, conduction failure or contact failure between the single element 12 and the second connector 22 can be prevented (see FIGS. 4 and 8).

More specifically, as shown in FIG. 8(A), since the chamfered portions 57 are formed at both ends of the pair of the folded strips e and e, as shown in FIG. 8(C), the second electrode faces 12c and 12d of the single element 12 are allowed to be slid and pushed into the insides of the first and second fitting portions 50 and 52. As a result of this, the pair of the folded strips e and e can be pushed to be elastically and smoothly widened, so that mounting the single element 12 to the second connector 22 can be facilitated.

Next, the constitution of the third connector is described. Although the third connector 23 is divided into a third connector 23a (see FIG. 10) for electrically connecting the first single element 12 of the thermoelectric conversion element array 11 with an external electrode, and a third connector 23b (see FIG. 11) for electrically connecting the last single element 12 of the thermoelectric conversion element array 11 with an external electrode, both of the third connectors 23a and 23b have the unfolded plate shown in FIG. 9 formed to be folded so as to obtain a desired shape.

In FIG. 9, the third connector 23 includes a first fitting portion 60 and a lead portion 64. The first fitting portion 60 is fitted into the first electrode face 12c (or the second electrode face 12d) of the single element 12 and secured (see FIG. 4). The lead portion 64 extends in a direction orthogonal to an end portion of the first fitting portion 60 and is connected electrically with an external electrode as another electrode (not shown). In FIG. 9, the first fitting portion 60 forms at both ends thereof a pair of fold strips e and e that holds end portions of a pair of principal faces 12a and 12b from both sides (see FIG. 4).

Here, regarding the third connector 23a, an unfolded plate shown in FIG. 9 is formed to be folded, so as to obtain a folded shape as shown in FIG. 10. In FIG. 10, the third connector 23 may be formed so that, first, the pair of the fold strips e and e is folded at an angle not less than a right angle, and then folded substantially at a right angle at the boundary between the first fitting portions 60 and the lead portion 64. Furthermore, the lead portion 64 is formed to be folded at a right angle. The third connector 23a may be folded to be formed in a bundle without undergoing three folding steps.

On the other hand, regarding the third connector 23b, an unfolded plate shown in FIG. 9 is formed to be folded to obtain substantially a flat shape as shown in FIG. 11. In FIG. 11, the third connector 23b is formed so that the pair of the fold strips e and e is folded at an angle not less than a right angle. It should be noted that the lead portion 64 may be cut to an appropriate length using a cutoff tool.

Then, each of the first fitting portions 60 of the pair of the third connectors 23a and 23b is fitted into the first electrode face 12c (or the second electrode face 12d) of the first and last single elements 12 of the thermoelectric conversion element array 11, and the lead portion 64 is connected to an external electrode (another electrode). With this constitution, the thermoelectric conversion element array 11 is electrically connected with an outer device.

In FIGS. 10 and 11, the fold strip e is folded at an angle not less than a right angle, and an installation width W1 of each of the first fitting portions 60 of the third connectors 23a and 23b is set so as to be smaller than the width W2 (see FIG. 4) of the electrode faces 12c and 12d of the single element 12. Therefore, when the single element 12 is pushed into each of the first fitting portions 60 to attach, the pair of the fold strips e and e is pushed to be elastically widened so that the first and second electrode faces 12c and 12d of the single element 12 can be secured to each of the first fitting portions 60 in a so-called one-touch style.

Next, an operation of the thermoelectric conversion module according to the present invention is described. In FIGS. 1 and 3, a cylindrical lead-in portion 14a and lead-out portion 14b are formed at both ends of the inner tube 14, respectively. Then, a high-temperature fluid or a low-temperature fluid is led-in from the lead-in portion 14a into the inner tube 14 and is led-out from the lead-out portion 14b. In the embodiment, a low-temperature fluid is led-in into the inner tube 14 (i.e. defined as a second fluid passage 102 for passing a low-temperature fluid inside the inner tube 14), and thus the outside of the outer tube 13 is defined as a first fluid passage 103 for passing a high-temperature fluid. It should be noted that heating the outer tube 13 externally also corresponds to passing a high-temperature fluid outside the outer tube 13. Furthermore, it may be configured so that the first fluid passage 103 for passing a high-temperature fluid inside the inner tube 14 is defined and the second fluid passage 102 for passing a low-temperature fluid outside the outer tube 13 is defined.

Incidentally, upon manufacturing the above-mentioned single element 12, first, CaCO₃, MnCO₃, and Y₂O₃ as well as pure water were added in a mixing pot in which milling balls were placed, the mixing pot was mounted to a vibration ball mill to vibrate for 2 hours, and the contents in the mixing pot were mixed.

Subsequently, the mixture obtained was filtered and dried, and then the dried mixture was provisionally calcined for 5 hours at 1200° C. by way of an electric furnace. Then, after this calcined body was pulverized by way of a vibration mill, the pulverized product was filtered and dried. Next, a binder was added to the dried pulverized product and dried, and then sorted and granulated. Subsequently, the granulated product was molded using a pressing machine, and this molded body was calcined for 5 hours by the electric furnace, to obtain a CaMnO₃-based single element as a sintered body.

This CaMnO₃-based single element includes a composition of Ca₁₋ₓYₓMnO₃, where x=0.0125. Furthermore, the size of each single element was a square of 8.3 mm×8.3 mm with a thickness of 2.45 mm. In addition, the Seebeck coefficient upon measuring was 220 μV/K and the resistivity was 0.014 Ωcm. Moreover, the resistance value of a single element was 0.057Ω and its weight was 0.70 g.

Then, upon manufacturing the thermoelectric conversion module 10, one face of the single element 12 is in close contact (not fixed) on a face opposite to a high-temperature side of which the thermal expansion is high so as to form a first insulating layer 100 (for example, an insulating material such as an insulating paste including aluminum nitride (AIN) or silica (SiO₂)) via an electrode, while the other face of the single element 12 is fixed on a face of a low-temperature side, which has a low thermal expansion and is disposed in a direction opposite to the face of the high-temperature side, so as to form a second insulating layer 101 (for example, an insulating layer formed by insulation processing such as anode oxidation processing) via an electrode (for example, see FIG. 6(C) or 7(A)). That is, in this embodiment, the first insulating layer 100 is in close contact on the opposite surface of the first fluid passage 103 (in this embodiment, outside of the outer tube) via an electrode, and the second fluid passage 101 (in this embodiment, inside of the inner tube) is fixed on the opposite surface of the second fluid passage 102 via an electrode.

For example, in the embodiment in FIGS. 1 and 3, regarding the inner tube 14, a rectangular tube made of aluminum with a thickness of approximately 1.5 mm may be used, and such a rectangular tube made of aluminum has advantages in excelling in a heat conduction characteristic due to being a rectangular tube made of stainless steel (SUS) and being generally inexpensive. In addition, the outer tube 13 may be formed by combining a pair of L-shaped channel materials made of stainless steel, and assembling is facilitated by combining the pair of L-shaped channel materials after arranging a plurality of the thermoelectric conversion element arrays 11 to the inner tube 14.

Here, characteristics of the thermoelectric conversion module 10 using the abovementioned single element 12 were examined. As shown in FIG. 12, the thermoelectric conversion module 10 is set at a heat insulating receptacle (SUS) 71 (the thermoelectric conversion module 10 is set to a condition of passing through the heat insulating receptacle 71), and the heat insulating receptacle 71 is disposed on a portable gas burner to heat the heat insulating receptacle 71. Then, cooling water was led-in from the lead-in portion 14a.

As shown in FIG. 12, a thermocouple 73a that is disposed at a surface of the heat insulating receptacle 71 is connected to a digital multi-meter (a digital voltmeter) for a thermocouple and an output terminal of the thermoelectric conversion module is connected to a digital voltmeter for characteristics measurement 74 to measure characteristics of the thermoelectric conversion module 10.

As a result of this, when an ambient temperature of the thermoelectric conversion module 10 was 656° C., 7.359 V of open voltage and 873 mW of power output were obtained, and the power output was barely reduced even when lowering the fluid velocity of the cooling water down to 600 ml/min. Then, warm water of 41° C. was obtained from the lead-out portion 14b, and thus it could be confirmed that it is functioned as a water boiler. Then, upon measuring the resistance value of the thermoelectric conversion module 10 after the examination, it became 17.5Ω, which was increased by 2Ω, compared to the initial resistance value.

Furthermore, upon examining warpage in the thermoelectric conversion module, it can be confirmed that warpage scarcely occurred. In the thermoelectric conversion module 10 illustrated, as described above, since one face of the single element 12 is in close contact on a face opposite to a high-temperature side of which thermal expansion is high so as to form a first insulating layer 100 (coating an insulating material such as a conductive paste including aluminum nitride (AIN), silica (SiO₂), and the like)) via an electrode, while the other face of the single element 12 is fixed on a face of a low-temperature side, which has low thermal expansion and is disposed in a direction opposite to the face of the high-temperature side, so as to form a second insulating layer 101 (performing insulation processing such as anode oxidation processing) via an electrode, it was found that the occurrence of the warpage due to the difference between thermal expansions of the sides of the heating face and the cooling face could be suppressed.

As a result of this, it is no longer necessary to use a fixing member for preventing warpage as in the flat-plate module, and it is possible to simplify the constitution of the thermoelectric conversion module, as well as be made a thermoelectric conversion module that excels in economy and versatility.

Next, an applied example of the above-mentioned thermoelectric conversion module 10 is described. FIG. 13 illustrates an example for generating electric power through heating by way of incineration heat of a garbage incinerator 81, in which the thermoelectric conversion module 10 is accommodated in the garbage incinerator 81 and the thermoelectric conversion module 10 is heated by way of incineration heat from the outside of the outer tube 13. On the other hand, tap water, which is the low-temperature fluid, from the lead-in portion 14a is led-in from a faucet 82.

Since the single element 12, i.e. the thermoelectric conversion element array 11, is in contact with the outer face of the inner tube 14 and the inner face of the outer tube 13, thermal energy that is produced between a high-temperature side and a low-temperature side of the single element 12 is converted to electric energy, which is supplied as electric power to an external electrode via the pair of third connectors 23a and 23b (see FIG. 1). Then, an electric lamp 83 connected to the external electrode lights up. Furthermore, tap water is warmed while passing through the inner tube 14, and supplied as heated water from the lead-out portion 14b to a tank 84.

In this way, with the thermoelectric conversion module 10 according to the present invention, since a face of the single element 12 that is arranged between the outer tube 13 and the inner tube 14 using the double angular cylinder 15 is defined as a heating face and the other face that faces the heating face is defined as a cooling face, so as to form the first insulating layer by being in close contact with the heating face via an electrode as well as to form the second insulating layer by being fixed to the cooling face via an electrode, the occurrence of warpage due to the difference of thermal expansions between the heating face side and the cooling face side can be suppressed even when constituting the thermoelectric conversion module using the flat-plate single element 12. As a result of this, since it is no longer necessary to use a fixing member for preventing warpage of the thermoelectric conversion module, it is possible to simplify the constitution of the thermoelectric conversion module as well as to improve energy conversion efficiency.

It should be noted that, as described with reference to FIG. 2, with a constitution in which the radiating fin 13a is fixed on an outer surface of the outer tube 13, it is possible to more satisfactorily suppress warpage of the thermoelectric conversion module itself because of the radiating fin 13a. Furthermore, when defining the first fluid passage 103 for passing a high-temperature fluid inside the inner tube 14 and defining the second fluid passage 102 for passing a low-temperature fluid outside the outer tube 13, the first insulating layer 100 is in close contact on a face opposite to an inside (the first fluid passage 103) of the inner tube via an electrode and the second insulating layer 101 is fixed on a face opposite to an outside (the second fluid passage 102) of the outer tube via an electrode.

Furthermore, as a double angular cylinder, the cross-section may be in a triangle shape, and further may be in a square shape. In addition, it may be in a polygonal shape with four or more corners. In either case, it may be any shape as long as it has a flat face extending in an axial direction.

In addition, “another electrode” or “the other electrode” may be an electrode of another thermoelectric conversion element that is electrically connected with a conductive member (connector), may be an external electrode to which the thermoelectric conversion module is connected electrically, or may be either one of the first and last electrodes of the thermoelectric conversion element array that is formed by connecting a plurality of thermoelectric conversion elements, which is arranged in parallel, by way of a conductive member in a prescribed direction.

In the thermoelectric conversion module 10 constituted as described above, thermal energy that is produced between a high-temperature portion and a low-temperature portion of each single element 12 is converted to electric energy, and this electric energy is supplied as electric power to an external electrode via the third connectors 23a and 23b (see FIG. 1).

In the embodiment as described above, regarding the adjacent single elements 12, the first electrode face 12c of the one single element and the second electrode face 12d of the other single element are electrically connected via the first and second connectors 21 and 22 of a prescribed shape. In this way, as the single elements 12 are electrically connected by way of these first and second connectors 21 and 22, using the first and second connectors (a connector in which a conventional connecting lead line and a fitting portion are integrated) that can be said to integrally incorporate the lead line instead of a conventional connecting lead line, it is possible to provide the thermoelectric conversion module 10 with high electrical reliability without conduction failure.

In this case, by mounting by way of securing the first to third connectors 21, 22, and 23 in advance in a prescribed alignment on the inner tube 14 and fitting each single element into fitting portions of these first to third connectors 21, 22, and 23, so as to form alignments A1 to A4 of the single elements 12 that are electrically connected with each other, it is possible to manufacture the thermoelectric conversion module 10 easily. This can reduce a burden for assembling (manufacturing process) (improving assembling performance).

Furthermore, in the present embodiment, the single element 12 is arranged vertically in a vertically long manner so that the electrode faces 12c and 12d thereof face the outer tube 13 and the inner tube 14, and the principal faces 12a and 12b are substantially vertical with respect to the outer tube 13 and the inner tube 14. In this way, as the single element 12 is aligned to be arranged vertically in a vertically long manner, as described above, its length in a height direction of the single element 12 is longer, element resistance is increased, electric current is regulated, and the difference in temperature between both ends of the element is easily produced, thereby enhancing electromotive force and thus obtaining high thermoelectric conversion efficiency.

Furthermore, in the thermoelectric conversion module 10 according to the present embodiment, the alignments A1 to A4 of the single element 12 is sandwiched and held between the outer tube 13 and the inner tube 14. In this way, as the alignments A1 to A4 of the single element 12 is held by the outer tube 13 and the inner tube 14, and fixed so as to put pressure from both sides of the single element 12, a contact area between an electrode face of the single element 12 and the first to third connectors becomes larger, and therefore, it is possible to reduce conduction failure and contact failure, which improves electrical reliability.

Furthermore, in the thermoelectric conversion module 10 according to the present embodiment, three types of connectors (the first to third connectors 21, 22, and 23) of appropriate shapes that correspond to electrically connecting locations are used. Therefore, it is possible to achieve good connectivity of the vertically long single element 12 as well as efficient modularization, and moreover, it is possible to realize various types of alignment for the single element, depending on the application since the connectors can be used according to a type of connection of the single element 12.

In the thermoelectric conversion module 10 according to the present embodiment, since the single element 12 is formed by a sintered body of a composite metal oxide, it is possible to improve heat resistance and mechanical strength. More specifically, since an oxide of a composite metal element is an oxide of which constituent elements are alkali earth metal, rare earth, and manganese, it is possible to further improve heat resistance at high temperatures.

It should be noted that the present invention is not restricted to the abovementioned embodiments, and naturally can be modified in various ways to be implemented without deviating from the scope of the invention. For example, in the abovementioned embodiment, although a modular structure is exemplified in which a plurality of semi-conductors of an identical conductive type is provided in a prescribed alignment and electrodes that are located on both sides of these semi-conductor elements are connected by a connector, the present invention can be applied to a modular structure in which an n-type semi-conductor element and a p-type semi-conductor element are arranged alternately and adjacent semi-conductor elements are connected with each other by an electrode.

Furthermore, a shape of a connector is also not limited to the embodiment previously described. For example, in FIGS. 9 to 11, as a modified example regarding the third connector 23, a shape in which the lead portion 64 protrudes from a center of the first fitting portion 60 of the third connector can be considered. In such a shape, two types of connectors can be obtained depending on the existence of a fold in a middle portion, and thus, it is possible to extend the lead portion 64 within an identical flat face from the first single element 12 and the last single element 12 over the entire alignment so as to conform to a positional relationship of an external electrode.

In the thermoelectric conversion module 10 as previously described, in a condition in which the single element 12 is not fixed to a connector, a distance between the fitting portions of the connectors that are fitted into both sides of the single element 12 may be shorter than a distance between the electrode faces of the single element 12. For example, in FIG. 7(A), regarding the first connector 21 at the alignment A1, the fitting portions are adjacent to face each other so that the single elements 12 can be inserted into the one first connector 21 including the first fitting portion 40 that is fitted into the first electrode face 12c and the other first connector 21 including the second fitting portion 42 that is fitted into the second electrode face 12d. In this case, as shown in FIG. 7(B), in a condition in which the single element 12 is not fixed, it may be set so that a distance Y between the first fitting portion 40 of the adjacent one first connector 21 and the second fitting portion 42 of the other first connector 21 is shorter than a distance X between the first electrode face 12c and the second electrode face 12d of the single element 12.

When done in this way, in a case in which the single element 12 is fitted into the first connector 21 of a substantially U-shape, of which a tip is made narrower, the tips of the fitting portions 40 and 42 are pushed to be widened, so that the single element 12 is fitted. This allows the tips of the fitting portions 40 and 42 to press the single element 12, which can hold the single element 12 securely by the first connector 21.

Furthermore, as the single element 12 is mounted, the fitting portions 40 and 42 facing each other become substantially parallel, and a contact area between the electrodes 12c and 12d of the first connector 21 and the fitting portions 40 and 42 at the thermoelectric conversion module can be made uniform. As a result of this, it is possible to improve thermoelectric efficiency. Naturally, such a constitution can be applied to the second and third connectors 22 and 23.

In the thermoelectric conversion module 10 as described previously, in order to facilitate insertion and fitting of the single element 12 to the first to third connectors 21, 22, and 23, an end edge of the single element 12 may be rounded. That is, the end edge of the single element 12 may be rounded by a prescribed curvature. In this way, in a case of inserting the single element 12 into the first to third connectors 21, 22 and 23, the single element 12 can be inserted into the first to third connectors smoothly without binding. It should be noted that such a shape of the single element 12 can be realized easily by modifying a die during molding as appropriate.

Furthermore, in view of improving an insertion property of the single element 12 into the first to third connectors 21, 22, and 23, another constitution can be considered. For example, in the first connector 21, after the single element 12 is guided to be mounted to the end edges of the first and second fitting portions 40 and 42 and the single element 12 is mounted to the first and second fitting portions 40 and 42, a guiding portion (not shown) that can be folded inside so as to be alongside the single element 12 may be provided. This guiding portion, for example, is shaped to be a strip, and normally extends so as to stretch out toward outside.

In this way, as long as the first and second fitting portions 40 and 42 are provided with the guiding portions, mounting of the single element 12 with the first connector 21 can be facilitated (more specifically, the efficiency is enhanced in a case in which an installation width of a fitting portion of a connector is set to be smaller than a width of an electrode of a single element), and therefore, it is possible to improve assembly performance.

Furthermore, since the abovementioned guiding portion can be folded so as to be alongside the single element 12, the single element can be fixed at the guiding portion after mounting the single element 12 with the first connector 21, and thus it is possible to improve mounting stability of the single element 12 at the first connector 21. Therefore, it is possible to provide the thermoelectric conversion module 10 with high electrical reliability without conduction failure. Naturally, such a constitution can be applied to the second and third connectors 22 and 23 as well.

Furthermore, in view of improving an insertion property of the single element 12 into the first to third connectors 21, 22, and 23, another constitution can be considered. For example, in the first connector 21, the first and second fitting portions 40 and 42 (more specifically, each fold portion e) may be provided with an engaging portion of hook shape (not shown) that is engaged in a fixing groove that is formed on both upper and lower sides of the single element 12.

In this way, since the engaging portion of the first connector 21 during mounting is engaged in the fixing groove of the single element 12, and thus, the single element 12 is securely mounted with respect to the first connector, it is possible to provide a thermoelectric conversion module with high electrical reliability without conduction failure. Naturally, such a constitution can be applied to the second and third connectors 22 and 23 as well.

Furthermore, in view of improving an insertion property of the single element 12 into the first to third connectors 21, 22, and 23, another constitution can be further considered. For example, in the first connector 21, the connecting portion 44 that constitutes the lead portion 45 may be provided with a parallel portion (not shown) that extends from the electrodes 12c and 12d on both upper and lower sides on a lateral face between the electrodes 12c and 12d of the single element 12. When the lead portion 45 includes such a parallel portion, a contact area between the lead portion 45 (the connecting portion 44) and the single element 12 becomes larger, and thus the single element 12 can be held with a larger area, which can improve mounting stability of the single element 12 at the first connector 21.

It should be noted that, in addition to present constitution or apart from the present constitution, in order to ensure additional mounting stability, a fixing member (not shown) including comb-teeth that can be inserted into both sides of the single element 12 and having electrical insulating property may be provided. When such a fixing member including comb-teeth is provided, since the comb-teeth are inserted into both sides of one or a plurality of single elements 12, and the single elements 12 are supported from both sides by way of the comb-teeth, it is possible to improve mounting stability of the single element 12 at the thermoelectric conversion module.

Furthermore, since the abovementioned fixing member has an electrical insulating property to prevent short-circuiting, the single elements 12 are exposed and electrical insulation can be at a lateral side of the single elements 12 facing each other (preventing short-circuiting of the single elements), which is especially advantageous. It should be noted that, in this case, for example, it is preferable that aluminum anode oxidation processing (alumite treatment) is conducted when mounting the fixing member to a cooling face side (a low-temperature side), and stainless steel (SUS) is mounted by PVD (physical vapor deposition) or glass coating is conducted to the fixing member when mounting the fixing member to a heating face side (a high-temperature side).

Furthermore, the following constitution may be added to the abovementioned embodiment. For example, the first fitting portions 40, 50, 60 (naturally, it may be the second fitting portion) of the first to third connectors 21, 22, and 23 may be provided with a strip for short-circuiting (not shown) that can be folded and has a sufficient length for electrically contacting an adjacent connector when folded. This strip for short-circuiting, for example, is fixed at the fold strip e and extends along the fold strip e, a penetrating hole into which a short circuit line for repairing (for example, a wire) is penetrated is provided at the extending portion that further extends by a prescribed length from an end edge of the fold strip e.

With such a constitution, in a case in which one single element 12 is damaged or deteriorated to cause conduction failure with the first connector 21, the strip for short-circuiting at both sides of the single element 12 is folded and, using the fold portion, the elements at both sides of the single elements 12 is allowed to be electrically short-circuited by way of the short-circuit line for repairing.

In this way, by providing the strip for short-circuiting to each connector in advance, it is possible to repair the single element 12 by easily conducting between connectors without performing a difficult operation such as replacing a single element 12 even, when any of the single elements 12 are damaged (deteriorated).

1. A thermoelectric conversion module, comprising:
a double angular cylinder that includes an inner tube, and an outer tube disposed at a predetermined spacing on the same axis as the inner tube;
electrodes that are respectively arranged on opposing faces of the inner tube and the outer tube; and
a thermoelectric conversion element that is connected to the electrodes.

2. The thermoelectric conversion module according to claim 1, wherein
in the thermoelectric conversion element, one face disposed in an opposing orientation is defined as a heating face, and the other face is defined as a cooling face,
one of an inside of the inner tube and an outside of the outer tube is defined as a first fluid passage in which high-temperature fluid flows, and the other is defined as a second fluid passage in which low-temperature fluid flows, and
wherein the thermoelectric conversion element includes: a first insulation layer that is adhered to the heating face and that is formed through the electrodes on an opposite face of the first fluid passage; and
a second insulation layer that is fixed to the cooling face and that is formed through the electrodes on an opposite face of the second fluid passage.

3. The thermoelectric conversion module according to claim 2, wherein a radiating member is disposed on a face defined as the second fluid passage.

4. The thermoelectric conversion module according to claim 3, wherein the thermoelectric conversion element is formed in a flat-plate shape, and an outer face of the inner tube is formed in a flat-plate shape and extends in an axial direction.

5. The thermoelectric conversion module according to claim 4, wherein the thermoelectric conversion element is a sintered cell comprising a composite metal oxide.

6. The thermoelectric conversion module according to claim 5, wherein the electrodes are obtained by applying a conductive paste to the sintered cell, and sintering.

7. The thermoelectric conversion module according to claim 6, wherein each of the thermoelectric conversion elements is molded from an identical material.

8. The thermoelectric conversion module according to claim 7, further comprising a conductive member of a predetermined shape electrically connecting with a second electrode that is different from the electrode,
wherein the conductive member includes a first fitting portion that fits together with and is secured to one of the electrodes, and a lead portion that is electrically connected to the second electrode, which is different from the electrode with the first fitting portion.

9. The thermoelectric conversion module according to claim 8, wherein the second electrode is an external electrode to which the thermoelectric conversion module connects electrically.

10. The thermoelectric conversion module according to claim 8, wherein the second electrode is the electrode of a second thermoelectric conversion element, and the lead portion includes a second fitting portion that fits together with and is secured to another of the electrodes of the second thermoelectric conversion element.

11. The thermoelectric conversion module according to claim 8, wherein the conductive member includes:
a first connector that forms a thermoelectric conversion element array by way of connecting in a predetermined direction a plurality of the thermoelectric conversion elements, which are arranged in parallel, to each other; and
a second connector that electrically connects the second electrode and one of the electrodes of any one of a first or last thermoelectric conversion element of the thermoelectric conversion element array connected to the first connector.

12. The thermoelectric conversion module according to claim 11, wherein the second electrode connected by the second connector is another one of the electrodes of any one of a first or last thermoelectric conversion element of another of the thermoelectric conversion element arrays.

13. The thermoelectric conversion module according to claim 1, wherein the thermoelectric conversion element is formed in a flat-plate shape, and an outer face of the inner tube is formed in a flat-plate shape and extends in an axial direction.

14. The thermoelectric conversion module according to claim 2, wherein the thermoelectric conversion element is formed in a flat-plate shape, and an outer face of the inner tube is formed in a flat-plate shape and extends in an axial direction.

15. The thermoelectric conversion module according to claim 1, wherein the thermoelectric conversion element is a sintered cell comprising a composite metal oxide.

16. The thermoelectric conversion module according to claim 2, wherein the thermoelectric conversion element is a sintered cell comprising a composite metal oxide.

17. The thermoelectric conversion module according to claim 3, wherein the thermoelectric conversion element is a sintered cell comprising a composite metal oxide.

18. The thermoelectric conversion module according to claim 1, wherein each of the thermoelectric conversion elements is molded from an identical material.

19. The thermoelectric conversion module according to claim 2, wherein each of the thermoelectric conversion elements is molded from an identical material.

20. The thermoelectric conversion module according to claim 3, wherein each of the thermoelectric conversion elements is molded from an identical material.
